(19) United States
(12) Patent Application Publication
(10) Pub. No.: US 2025/0290204 A1
(43) Pub. Date: Sep. 18, 2025

(54) METHOD OF MANUFACTURING GAS BARRIER FILM

(71) Applicant: FUJIFILM Corporation, Tokyo (JP)

(72) Inventors: Yoshihiko MOCHIZUKI, Minamiashigara-shi (JP); Eijiro IWASE, Minamiashigara-shi (JP)

(73) Assignee: FUJIFILM Corporation, Tokyo (JP)

(21) Appl. No.: 19/226,533

(22) Filed: Jun. 3, 2025

Related U.S. Application Data
(63) Continuation of application No. PCT/JP2024/001316, filed on Jan. 18, 2024.

(30) Foreign Application Priority Data
Jan. 19, 2023 (JP) 2023-006412

(51) Int. Cl. C23C 16/54; C23C 16/34

(52) U.S. Cl. CPC C23C 16/545; C23C 16/345

(57) ABSTRACT

An object is to provide a method of manufacturing a gas barrier film, the method including forming an inorganic layer through roll-to-roll, in which even in a case where a film formation length is long, an inorganic layer having a desired film property can be stably formed. This method includes forming an inorganic layer by dual-frequency capacitively coupled plasma CVD, in which the inorganic layer is formed using a film forming device including a film formation chamber where the inorganic layer is formed on a support and an unwinding chamber where the support on which the inorganic layer is to be formed is fed, the support on which the inorganic layer is formed is wound, and the film formation chamber is separated from the unwinding chamber by a partition wall, monosilane gas, ammonia gas, and hydrogen gas as film forming gas are supplied at a fixed flow rate to form the inorganic layer, and an exhaust amount is increased over time during the formation of the inorganic layer to maintain a monosilane gas concentration in the film formation chamber to be fixed, and a detoxifying treatment of detoxifying the exhaust gas is performed. As a result, the object is achieved.

### CROSS-REFERENCE TO RELATED APPLICATIONS

This application is a Continuation of PCT International Application No. PCT/JP2024/001316 filed on Jan. 18, 2024, which claims priority under 35 U.S.C. § 119(a) to Japanese Patent Application No. 2023-006412 filed on Jan. 19, 2023. The above applications are hereby expressly incorporated by reference, in their entirety, into the present application.

### BACKGROUND OF THE INVENTION

### 1. Field of the Invention

The present invention relates to a method of manufacturing a gas barrier film. Specifically, the present invention relates to a method of manufacturing a gas barrier film, the method including forming an inorganic layer on a support.

### 2. Description of the Related Art

An infusion bag for accommodating a drug that is denatured by water or oxygen and a tube or a packaging bag for accommodating food that also deteriorates due to water or oxygen are required to have high gas barrier properties from the viewpoint of improving storage stability of a drug or the like.

In the infusion bag and the like, gas barrier properties are improved by bonding a gas barrier film to a surface.

Gas barrier films are used in order to protect elements and the like that deteriorate due to water and/or oxygen, or the like, such as solar cells, organic electroluminescence elements, and illumination devices using quantum dots.

As a gas barrier film having high gas barrier properties, there is known an organic-inorganic laminated gas barrier film where one or more combinations of inorganic layers that exhibit gas barrier properties and organic layers that are underlying layers of the inorganic layers are provided on a support such as a resin film.

For example, as the organic-inorganic laminated gas barrier film, JP2013-203050A discloses a gas barrier film including: a support (substrate) that has a surface consisting of an organic material; an inorganic layer (inorganic film) that is formed on the support and includes silicon nitride as a major component; and a mixed layer that is formed in an interface between the substrate and the inorganic film, and includes components derived from the organic material and the inorganic film, in which a compositional ratio N/Si between nitrogen and silicon in the inorganic layer is 1.00 to 1.35, the inorganic layer has a film density of 2.1 to 2.4 g/cm³ and a film thickness of 10 to 60 nm, and the mixed layer has a thickness of 5 to 40 nm.

Further, JP2013-203050A discloses a method of manufacturing the gas barrier film, the method including: forming an inorganic layer that includes silicon nitride as a major component on a support by capacitively coupled plasma CVD using a film forming unit while transporting an elongated support that has a surface consisting of an organic material in a longitudinal direction, the electrode pair being disposed such that the support that is transported is interposed in the electrode pair, in which during the formation of the inorganic film, plasma excitation power with a high frequency of 10 to 100 MHz is supplied to one electrode in the electrode pair, and bias power that has a frequency of 0.1 to 1 MHz that is lower than the frequency of the plasma excitation power and is 0.02 to 0.5 times the plasma excitation power is supplied to the other electrode in the electrode pair.

### SUMMARY OF THE INVENTION

In the gas barrier film and the manufacturing method thereof disclosed in JP2013-203050A, with the above-described configuration, a gas barrier film having high gas barrier properties, high transparency, and excellent durability and flexibility is realized.

However, according to an investigation by the present inventors, not only in the method of manufacturing the gas barrier film described in JP2013-203050A but also in the method of manufacturing a gas barrier film where an inorganic layer including silicon nitride or the like as a major component is formed through roll-to-roll described in JP2013-203050A, in a case where a film formation length, that is, a length of the support on which the inorganic layer is continuously formed exceeds, for example, 500 m, the film property of the inorganic layer changes, and there is a problem in that the inorganic layer is likely to be broken after the change.

An object of the present invention is to solve the above-described problem of the related art and to provide a method of manufacturing a gas barrier film, the method including forming an inorganic layer through roll-to-roll, in which even in a case where a film formation length is long, an inorganic layer having a desired film property can be stably formed.

In order to achieve the object, the present invention has the following configurations.
[1] A method of manufacturing a gas barrier film, the method comprising:
forming an inorganic layer on a surface of a support through roll-to-roll,
in which the inorganic layer is formed using a film forming device including
   a film formation chamber where the inorganic layer is formed on the support using a film formation drum for winding and transporting the support and a film formation electrode facing the film formation drum by dual-frequency capacitively coupled plasma CVD of supplying power to the film formation drum and the film formation electrode, and
   an unwinding chamber where the support on which the inorganic layer is to be formed is fed from a support roll to the film formation chamber, the support on which the inorganic layer is formed in the film formation chamber is wound in a roll shape, and the film formation chamber is separated from the unwinding chamber by a partition wall having a passage portion of the support,
monosilane gas, ammonia gas, and hydrogen gas are supplied to the film formation chamber at a fixed flow rate to form the inorganic layer on the support in the film formation chamber, and an exhaust amount of exhaust gas exhausted from the film formation chamber is increased over time during the formation of the inorganic layer to maintain a concentration of monosilane gas in the film formation chamber to be fixed, and
a detoxifying treatment of detoxifying the exhaust gas is performed.
[2] The method of manufacturing a gas barrier film according to [1],
in which in a case where a concentration of monosilane gas in the film formation chamber at start of film formation is normalized to 1, the exhaust amount of the exhaust gas from the film formation chamber is increased over time such that the concentration of monosilane gas in the film formation chamber is 0.9 to 1.1 during the formation of the inorganic layer.
[3] The method of manufacturing a gas barrier film according to [1] or [2],
in which a pressure of the unwinding chamber is decreased over time during the formation of the inorganic layer.
[4] The method of manufacturing a gas barrier film according to any one of [1] to [3],
in which the power that is supplied to the film formation electrode is decreased over time during the formation of the inorganic layer.
[5] The method of manufacturing a gas barrier film according to any one of [1] to [4],
in which in the detoxifying treatment of the exhaust gas, monosilane gas and ammonia gas are removed from the exhaust gas containing monosilane gas, ammonia gas, and hydrogen gas using a porous material.
[6] The method of manufacturing a gas barrier film according to any one of [1] to [5],
in which a ratio of a flow rate of hydrogen gas to a flow rate of monosilane gas supplied to the film formation chamber is 7 or more in terms of a flow rate ratio “hydrogen gas/monosilane gas”.
[7] The method of manufacturing a gas barrier film according to any one of [1] to [6],
in which inert gas is supplied to the exhaust gas at a position upstream or downstream of the detoxifying treatment such that a hydrogen gas concentration in the exhaust gas that is emitted to the atmosphere is 4% or less.
[8] The method of manufacturing a gas barrier film according to any one of [1] to [7],
in which monosilane gas in the detoxified exhaust gas is detected by a detector, and in a case where the detector detects monosilane gas, the formation of the inorganic layer and the exhaust of the exhaust gas from the film formation chamber are stopped.
[9] The method of manufacturing a gas barrier film according to [8],
in which a normal exhaust flow channel, a second detoxifying treatment flow channel that detoxifies the exhaust gas, and a flow channel switching unit that switches a flow channel of the exhaust gas to the normal exhaust flow channel or the second detoxifying treatment flow channel are provided downstream of the detector,
in a state where the detector does not detect monosilane gas, the flow channel switching unit switches the flow channel of the exhaust gas to the normal exhaust flow channel, and
in a case where the detector detects monosilane gas, the flow channel switching unit switches the flow channel of the exhaust gas to the second detoxifying treatment flow channel such that inert gas is introduced from a position upstream of a position where the detoxifying treatment of the exhaust gas is performed, remaining exhaust gas is swept away to the second detoxifying treatment flow channel, and the exhaust gas is detoxified.

With the method of manufacturing a gas barrier film according to the present invention, it is possible to provide a method of manufacturing a gas barrier film, the method including forming an inorganic layer through roll-to-roll, in which even in a case where a film formation length is long, an inorganic layer having a desired film property can be stably formed.

### BRIEF DESCRIPTION OF THE DRAWINGS

FIG. 1 is a diagram conceptually showing an example of an inorganic film forming device that performs a method of manufacturing a gas barrier film according to the present invention.

FIG. 2 is a diagram conceptually showing an example of a gas barrier film manufactured using the method of manufacturing a gas barrier film according to the present invention.

FIG. 3 is a diagram conceptually showing an example of an organic film forming device.

FIG. 4 is a diagram conceptually showing another example of an inorganic film forming device that performs the method of manufacturing a gas barrier film according to the present invention.

### DESCRIPTION OF THE PREFERRED EMBODIMENTS

Hereinafter, a method of manufacturing a gas barrier film according to an embodiment of the present invention will be described in detail based on a preferred embodiment shown in the accompanying drawings.

In the present invention, numerical ranges represented by “to” include numerical values before and after “to” as lower limit values and upper limit values.

Further, all the drawings described below are conceptual views for describing the present invention. Accordingly, a size, a thickness, a shape, a positional relationship, and the like of each of members are different from the actual ones.

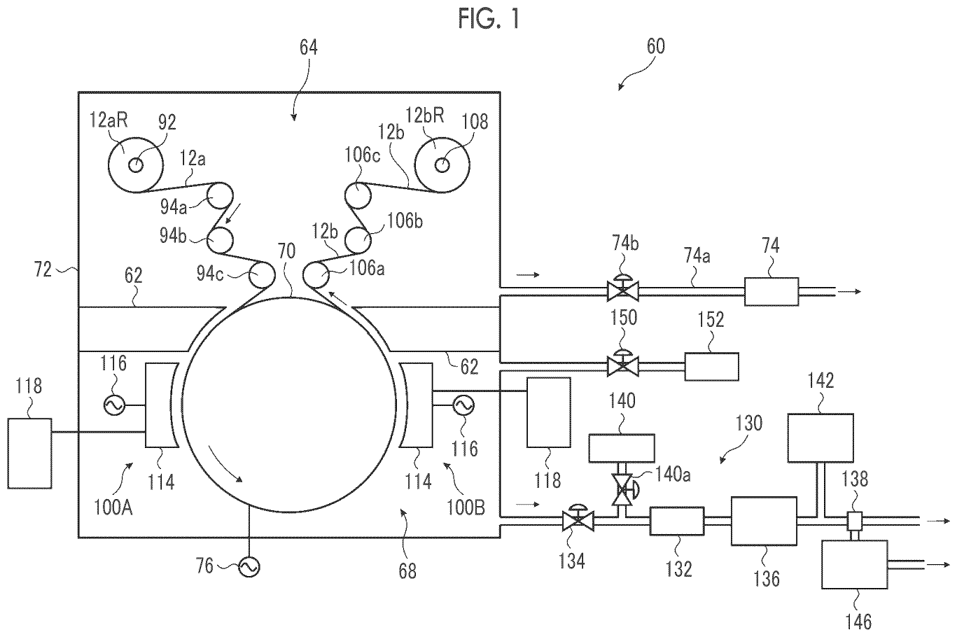

FIG. 1 conceptually shows an example of an inorganic film forming device that performs the method of manufacturing a gas barrier film according to the embodiment of the present invention.

In the inorganic film forming device 60 shown in FIG. 1, a vacuum chamber 72 is separated into an unwinding chamber 64 on the upper side in the drawing and a film formation chamber 68 on the lower side in the drawing through a partition wall 62.

The inorganic film forming device 60 forms an inorganic layer on a support 12a through roll-to-roll, and feeds the support 12a drawn from a support roll 12aR from the unwinding chamber 64 to the film formation chamber 68. In the unwinding chamber 64, a pump 74 for exhausting the unwinding chamber 64 to reduce the pressure through an exhaust pipe 74a is provided. Although not shown in the drawing, the exhaust pipe from the pump 74 is connected to a detoxifying device 136 described below to detoxify exhaust gas exhausted from the unwinding chamber 64.

In the film formation chamber 68, while transporting the support 12a wound around a film formation drum 70 in a longitudinal direction, an inorganic layer is formed on a surface of the support 12a. In the inorganic film forming device 60 of the example shown in the drawing, the film formation drum 70 also acts as a part of a partition wall for separating the unwinding chamber 64 and the film formation chamber 68 together with the partition wall 62. In addition, in the film formation chamber 68, an exhaust line 130 for exhausting the film formation chamber 68 to reduce the pressure is provided.

A support 12b on which the inorganic layer is formed is transported again to the unwinding chamber 64 and wound in a roll shape.

In the following description, “roll-to-roll” will also be referred to as “RtoR”.

Here, in the manufacturing method according to the embodiment of the present invention, the inorganic layer is formed on the surface of the support 12a by dual-frequency capacitively coupled plasma chemical vapor deposition (CVD) where monosilane gas, ammonia gas, and hydrogen gas are raw material gas (film forming gas). In the inorganic film forming device 60 of the example shown in the drawing, the inorganic layer is formed on the surface of the support 12a by dual-frequency capacitively coupled plasma CVD of supplying plasma excitation power to a shower electrode described below and supplying bias power to the film formation drum 70.

In addition, in the manufacturing method according to the embodiment of the present invention, during the formation of the inorganic layer, an exhaust amount of exhaust gas exhausted from the film formation chamber 68 through the exhaust line 130 increases over time, and the exhaust gas is detoxified in the exhaust line 130.

The above-described point will be described below.

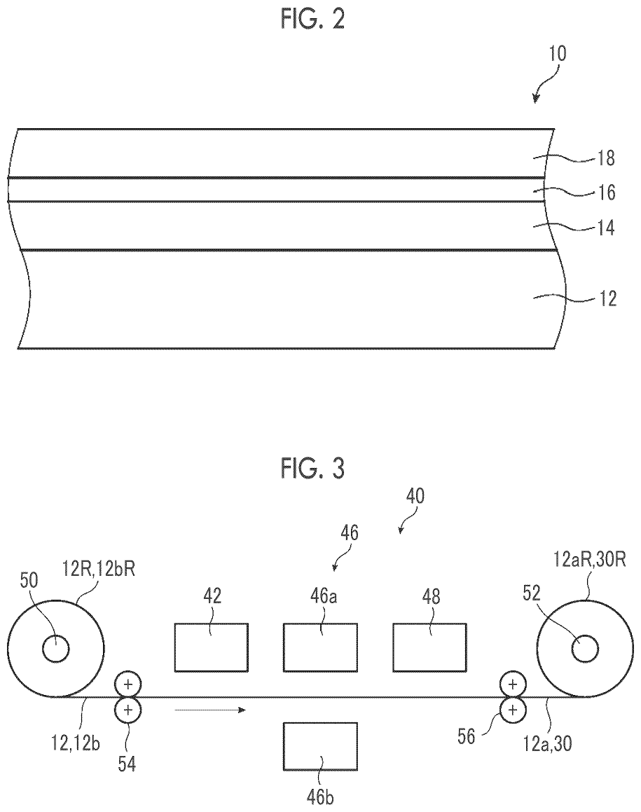

FIG. 2 conceptually shows an example of a gas barrier film manufactured using the method of manufacturing a gas barrier film according to the embodiment of the present invention.

A gas barrier film 10 shown in FIG. 2 includes a support 12, an underlying organic layer 14, an inorganic layer 16, and a protective organic layer 18. In the manufacturing method according to the embodiment of the present invention, this inorganic layer 16 is formed.

In the following description, the support 12 side of the gas barrier film 10 will also be referred to as “lower side”, and the protective organic layer 18 side thereof will also be referred to as “upper side”.

Although described below, the underlying organic layer 14 acts as an underlying layer of the inorganic layer 16 that is formed using the manufacturing method according to the embodiment of the present invention. The gas barrier film in the example shown in the drawing includes one set of a laminated structure of the underlying organic layer 14 and the inorganic layer 16. However, the gas barrier film manufactured using the manufacturing method according to the embodiment of the present invention is not limited to this example.

The gas barrier film manufactured using the manufacturing method according to the embodiment of the present invention may include two sets of laminated structures of the underlying organic layer 14 and the inorganic layer 16, the two sets of laminated structures including the underlying organic layer 14, the inorganic layer 16, the underlying organic layer 14, the inorganic layer 16, the protective organic layer 18 in this order from the support 12 side. In addition, the gas barrier film may include three sets of laminated structures of the underlying organic layers 14 and the inorganic layers 16, the three sets of laminated structures including the underlying organic layer 14, the inorganic layer 16, the underlying organic layer 14, the inorganic layer 16, the underlying organic layer 14, the inorganic layer 16, and the protective organic layer 18 in this order from the support 12 side. Further, the gas barrier film may include four or more laminated structures of the underlying organic layer 14 and the inorganic layer 16.

In addition, the gas barrier film manufactured using the manufacturing method according to the embodiment of the present invention may include only the support 12 and the inorganic layer 16, may include the support 12, the underlying organic layer 14, and the inorganic layer, or may include the support 12, the inorganic layer 16, and the protective organic layer 18.

The gas barrier film manufactured using the manufacturing method according to the embodiment of the present invention can adopt various layer configurations as long as they include the inorganic layer 16.

In the gas barrier film manufactured using the manufacturing method according to the embodiment of the present invention, in a case where the inorganic layer 16 includes a plurality of layers, at least one inorganic layer 16 may be formed using the manufacturing method according to the embodiment of the present invention.

However, in the gas barrier film manufactured using the manufacturing method according to the embodiment of the present invention, in a case where the inorganic layer 16 includes a plurality of layers, it is preferable that as many inorganic layers 16 as are formed in the manufacturing method according to the embodiment of the present invention, and it is most preferable that all of the inorganic layers 16 are formed in the manufacturing method according to the embodiment of the present invention.

### Support

As the support 12, a well-known sheet-shaped material (a film or a plate-shaped material) that is used as a support for various gas barrier films, various laminated functional films, and the like can be used.

A material of the support 12 is not particularly limited, and various materials can be used as long as the underlying organic layer 14 and the inorganic layer 16 can be formed. Preferable examples of the material of the support 12 include various resin materials.

Examples of the material of the support 12 include polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, polymethyl methacrylate resin (PMMA), polycarbonate (PC), polyacrylate, polymethacrylate, polypropylene (PP), polystyrene (PS), an acrylonitrile-butadiene-styrene copolymer (ABS), a cycloolefin copolymer (COC), a cycloolefin polymer (COP), triacetyl cellulose (TAC), and an ethylene-vinyl alcohol copolymer (EVOH).

Among these, PET is suitably used from the viewpoints of flexibility, strength, transparency, and the like.

Optionally, the support 12 may include an easy adhesion layer on one surface or both surfaces.

The thickness of the support 12 can be appropriately set depending on the use, the material, and the like.

The thickness of the support 12 is not limited and may be appropriately set depending on the forming material such that the mechanical strength of the gas barrier film can be sufficiently ensured and sufficient flexibility can be obtained.

The thickness of the support 12 is preferably 5 to 150 μm and more preferably 10 to 100 μm from the viewpoints that, for example, the mechanical strength of the gas barrier film can be sufficiently ensured, a gas barrier film having good flexibility can be obtained, the weight and thickness of the gas barrier film 10 can be reduced.

### Underlying Organic Layer

In the gas barrier film 10, the underlying organic layer 14 is formed on one surface of the support 12.

The underlying organic layer 14 consists of, for example, an organic compound obtained by polymerization (crosslinking or curing) of a monomer, a dimer, an oligomer, or the like.

The underlying organic layer 14 functioning as the underlayer of the inorganic layer 16 is an underlayer for appropriately forming the inorganic layer 16.

The underlying organic layer 14 formed on the surface of the support 12 embeds unevenness of the surface of the support 12, foreign matter attached to the surface, and the like to appropriately planarize the formation surface of the inorganic layer 16 such that the inorganic layer 16 can be appropriately formed.

As described above, in the present invention, the gas barrier film may include plural sets of laminated structures of the inorganic layer 16 and the underlying organic layer 14. In this case, the second or subsequent underlying organic layer 14 is formed on the inorganic layer 16. Even in this configuration, the underlying organic layer 14 functioning as the underlayer (the formation surface of the inorganic layer 16) of the inorganic layer 16 exhibits the same action.

In particular, by providing the underlying organic layer 14 on the surface of the support 12, the inorganic layer 16 that mainly exhibits gas barrier properties can be appropriately formed.

The underlying organic layer 14 is formed, for example, by curing a composition for forming an organic layer, that includes an organic compound (a monomer, a dimer, a trimer, an oligomer, a polymer, and the like). The composition for forming an organic layer may include one kind or two or more kinds of organic compounds.

The underlying organic layer 14 includes, for example, a thermoplastic resin and an organic silicon compound. Examples of the thermoplastic resin include polyester, a (meth) acrylic resin, a methacrylic acid-maleic acid copolymer, polystyrene, a transparent fluororesin, polyimide, fluorinated polyimide, polyamide, polyamide imide, polyether imide, cellulose acylate, polyurethane, polyether ether ketone, polycarbonate, an alicyclic polyolefin, polyarylate, polyethersulfone, polysulfone, fluorene ring-modified polycarbonate, alicyclic-modified polycarbonate, fluorene ring-modified polyester, and an acrylic compound. Examples of the organic silicon compound include polysiloxane.

From the viewpoints of high strength and glass transition temperature, it is preferable that the underlying organic layer 14 includes a polymer of a radically curable compound and/or a cationically curable compound having an ether group.

From the viewpoint of reducing the refractive index of the underlying organic layer 14, it is preferable that the underlying organic layer 14 includes a (meth) acrylic resin including, as a major component, a polymer of a monomer, an oligomer, or the like of (meth) acrylate. By reducing the refractive index of the underlying organic layer 14, transparency increases, and a light-transmitting property is improved.

It is more preferable that the underlying organic layer 14 includes a (meth) acrylic resin including, as a major component, a monomer, a dimer, an oligomer, or the like of a bi-or higher functional (meth)acrylate such as dipropylene glycol di(meth)acrylate (DPGDA), trimethylolpropane tri(meth)acrylate (TMPTA), or dipentaerythritol hexa(meth)acrylate (DPHA), and it is still more preferable that the underlying organic layer 14 includes a (meth)acrylic resin including, as a major component, a polymer of a monomer or a polymer such as a dimer, an oligomer of a tri- or higher functional (meth)acrylate. In addition, a plurality of (meth)acrylic resins may be used. The major component refers to a component having the highest content mass ratio among components included.

It is preferable that the composition for forming an organic layer includes an organic solvent, a surfactant, and a silane coupling agent in addition to the organic compound.

The thickness of the underlying organic layer 14 is not limited and can be appropriately set according to components in the composition for forming an organic layer, the support 12 used, and the like. The thickness of the underlying organic layer 14 is preferably 0.1 to 5 μm and more preferably 0.2 to 3 μm.

In a case where a plurality of underlying organic layers 14 are provided, that is, a case where plural sets of combinations of the inorganic layers 16 and the underlying organic layers 14 are provided, the thicknesses of the respective underlying organic layers 14 may be the same as or different from each other. In addition, in a case where a plurality of underlying organic layers 14 are provided, that is, in a case where plural sets of combinations of the underlying organic layers 14 and the inorganic layers 16 are provided as described above, the materials of the underlying organic layers 14 may be the same as or different from each other.

The underlying organic layer 14 can be formed with a well-known method depending on the forming material.

For example, the underlying organic layer 14 can be formed with a coating method of applying the above-described composition for forming an organic layer and drying the composition for forming an organic layer. During the formation of the underlying organic layer 14 with the coating method, the dried composition for forming an organic layer is irradiated with ultraviolet rays to polymerize (crosslink) the organic compound in the composition for forming an organic layer.

### Inorganic Layer

The inorganic layer 16 is a thin film including an inorganic compound, and is provided on a surface of the underlying organic layer 14. In the gas barrier film 10, the inorganic layer 16 mainly exhibits gas barrier properties.

In the manufacturing method according to the embodiment of the present invention, this inorganic layer of the gas barrier film is formed.

The surface of the support 12 includes a region such as unevenness or shadow of foreign matter to which the inorganic compound is not likely to adhere. On the other hand, by providing the underlying organic layer 14 and forming the inorganic layer 16 thereon, the region to which the inorganic compound is not likely to adhere is covered. Therefore, the inorganic layer 16 can be formed on the formation surface of the inorganic layer 16 without a gap.

Here, in the manufacturing method according to the embodiment of the present invention, the inorganic layer 16 is formed by dual-frequency capacitively coupled plasma CVD (dual-frequency capacitively coupled plasma (CCP)-CVD) where monosilane gas, ammonia gas, and hydrogen gas are raw material gas.

Accordingly, the inorganic layer 16 includes silicon nitride as a major component and includes a hydrogen inclusion of silicon nitride. In addition, hydrogen may be unavoidably incorporated into the inorganic layer 16.

The thickness of the inorganic layer 16 is not particularly limited and can be appropriately set such that desired gas barrier properties can be exhibited.

The thickness of the inorganic layer 16 is preferably 10 to 150 nm, more preferably 12 to 100 nm, and still more preferably 15 to 75 nm.

It is preferable that the thickness of the inorganic layer 16 is 10 nm or more from the viewpoint that the inorganic layer 16 stably exhibiting sufficient gas barrier performance can be formed. In addition, in a case where the inorganic layer 16 is generally brittle and is excessively thick, breakage, cracking, peeling, or the like may occur. However, by adjusting the thickness of the inorganic layer 16 to be 150 nm or less, the occurrence of breakage can be suppressed.

As described above, in a case where a plurality of inorganic layers 16 are provided, the thicknesses of the inorganic layers 16 may be the same as or different from each other.

### Protective Organic Layer

The protective organic layer 18 is a layer for protecting the inorganic layer 16, the layer consisting of an organic material. By providing the protective organic layer 18, breakage or the like of the inorganic layer 16 can be prevented.

A material for forming the protective organic layer 18 is not particularly limited, and various well-known organic compounds can be used as in the underlying organic layer 14.

In addition, as the material for forming the protective organic layer 18, a urethane skeleton acrylate polymer such as a polymerizable composition for forming a second organic layer described in paragraphs “0016” to “0027” of JP2015-171798A is suitably used. In addition, the composition for forming the protective organic layer 18 may include an additive such as a monomer, an oligomer, or a polymer, a polymerization initiator, and a silane coupling agent, in addition to the urethane skeleton acrylate polymer.

As the urethane skeleton acrylate polymer, for example, a commercially available product such as ACRIT 8BR series including ACRIT 8BR-930 that is an ultraviolet-curable urethane acrylic polymer manufactured by Taisei Fine Chemical Co., Ltd. may be used.

As the protective organic layer 18, a resin film may be used. In this case, a pressure-sensitive adhesive layer may be provided between the resin film as the protective organic layer and the inorganic layer.

Regarding the resin film as the protective organic layer and the pressure-sensitive adhesive layer, a resin layer (resin film) and a bonding layer described in WO2018/211850A and WO2019/049634A can be used.

The thickness of the protective organic layer 18 may be appropriately set depending on the material for forming the protective organic layer 18, the inorganic layer 16, and the like. According to an investigation by the present inventors, the thickness of the protective organic layer 18 is preferably 0.1 to 50 μm, more preferably 0.5 to 25 μm, and still more preferably 1 to 10 μm.

Hereinafter, by describing the method of manufacturing the gas barrier film 10 shown in FIG. 2, the method of manufacturing a gas barrier film according to the embodiment of the present invention will be described.

In a case where the gas barrier film 10 is manufactured, the underlying organic layer 14 is formed on the surface of the support 12.

FIG. 3 conceptually shows an organic film forming device 40 for forming the underlying organic layer 14 and the protective organic layer 18.

The organic film forming device 40 forms the underlying organic layer 14 and the protective organic layer 18 through RtoR. That is, the organic film forming device 40 applies the above-described composition for forming an organic layer for forming the underlying organic layer 14 or the protective organic layer 18 while transporting the elongated support 12 in a longitudinal direction, dries the applied composition for forming an organic layer, and polymerizes (cures) the organic compound in the composition for forming an organic layer by light irradiation to form the underlying organic layer 14 and the protective organic layer 18.

The organic film forming device 40 in the example shown in the drawing includes, for example, an application unit 42, a drying unit 46, a light irradiation unit 48, a rotating shaft 50, a winding shaft 52, and transport roller pairs 54 and 56.

In the organic film forming device 40 shown in FIG. 3, in a case where the underlying organic layer 14 is formed, a support roll 12R where the elongated support 12 is wound is charged into the rotating shaft 50 of the organic film forming device 40.

In a case where the support roll 12R is charged into the rotating shaft 50, the support 12 is drawn from the support roll 12R, passes the application unit 42, the drying unit 46, and the light irradiation unit 48 through the transport roller pair 54, and reaches the winding shaft 52 through the transport roller pair 56, that is, a passes a predetermined transport path.

The support 12 drawn from the support roll 12R is transported to the application unit 42 by the transport roller pair 54, and a composition for forming an organic layer that forms the underlying organic layer 14 is applied to a surface of the support 12.

The composition for forming an organic layer that forms the underlying organic layer 14 includes an organic solvent, an organic compound (a monomer, a dimer, a trimer, an oligomer, a polymer, and the like) for forming the underlying organic layer 14, a surfactant, and a silane coupling agent as described above.

In addition, various well-known methods such as a die coating method, a dip coating method, an air knife coating method, a curtain coating method, a roller coating method, a wire bar coating method, and a gravure coating method can be used for applying the composition for forming an organic layer in the application unit 42.

Next, the support 12 to which the composition for forming an organic layer that forms the underlying organic layer 14 is heated by the drying unit 46 to remove the organic solvent, and dry the composition for forming an organic layer.

The drying unit 46 includes a drying unit 46a that performs heating and drying from the surface side (front surface side) to which the composition for forming an organic layer is applied and a drying unit 46b that performs heating and drying from the opposite surface side (back surface side), and dries the composition for forming an organic layer from both of the front surface side and the back surface side. In the drying unit 46, only any one of the drying unit 46a or the drying unit 46b may be used.

Heating in the drying unit 46 may be performed using a well-known method for heating a sheet-shaped material. For example, the drying unit 46a on the front surface side is a hot-air drying unit, and the drying unit 46b on the back surface side is a heating roller (a guide roller having a heating mechanism).

Next, the support 12 in which the composition for forming an organic layer that forms the underlying organic layer 14 is dried is irradiated with ultraviolet rays or the like by the light irradiation unit 48 such that the organic compound is polymerized (crosslinked) and cured to form the underlying organic layer 14. Further, optionally, the curing of the organic compound that forms the underlying organic layer 14 may be performed in an inert atmosphere such as a nitrogen atmosphere.

The light irradiation unit 48 is optionally provided. That is, in a case where the effect by the ultraviolet irradiation or the like of the underlying organic layer 14 is unnecessary, the organic film forming device 40 does not need to drive the light irradiation unit 48, or does not need to include the light irradiation unit 48.

The support 12 on which the underlying organic layer 14 is formed is transported by the transport roller pair 56 and wound into a roll shape by the winding shaft 52.

Optionally, in the transport roller pair 56, a protective film may be laminated on the surface of the underlying organic layer 14.

In a case where the formation of the underlying organic layer 14 having a predetermined length is finished, the support 12 is optionally cut. Next, a support 12a where the underlying organic layer 14 is formed is wound to form a support roll 12aR.

Next, the support roll 12aR is supplied to an inorganic film forming device 60 shown in FIG. 1, and the inorganic layer 16 is formed.

As described above, in the inorganic film forming device 60 shown in FIG. 1, a vacuum chamber 72 is separated into an unwinding chamber 64 on the upper side in the drawing and a film formation chamber 68 on the lower side in the drawing through a partition wall 62.

The inorganic film forming device 60 forms the inorganic layer on the support 12a on which the underlying organic layer 14 is formed through RtoR. In the inorganic film forming device 60, the support 12a drawn from a support roll 12aR is fed from the unwinding chamber 64 to the film formation chamber 68. In the film formation chamber 68, while transporting the support 12a wound around a film formation drum 70 in a longitudinal direction, the inorganic layer 16 is formed on a surface of the support 12a. The support 12b on which the inorganic layer is formed is transported again to the unwinding chamber 64, is wound around a winding shaft 108 in a roll shape, and a support roll 12bR on which the inorganic layer 16 is formed is obtained.

The method of manufacturing a gas barrier film according to the embodiment of the present invention is not limited to the formation of the inorganic layer 16 on the surface of the underlying organic layer 14 as shown in FIGS. 1 to 3.

That is, in the manufacturing method according to the embodiment of the present invention, for example, the inorganic layer 16 may be formed on the support 12, the inorganic layer 16 may be formed on a surface of an easy adhesion layer provided on the support 12, or the inorganic layer 16 may be formed on a surface of a functional film such as an antireflection film.

That is, in the method of manufacturing a gas barrier film according to the embodiment of the present invention, as the support, various well-known elongated sheet-shaped materials (films) can be used as long as the inorganic layer can be formed by dual-frequency capacitively coupled plasma CVD where monosilane gas, ammonia gas, and hydrogen gas are raw material gas through RtoR.

In particular, the manufacturing method according to the embodiment of the present invention is suitably used for forming an inorganic layer in an organic-inorganic laminated gas barrier film including a combination of the underlying organic layer 14 and the inorganic layer 16 shown in FIG. 2.

In the unwinding chamber 64, a rotating shaft 92, pass rollers 94a to 94c, pass rollers 106a to 106c, and a winding shaft 108 are disposed.

In addition, the pump 74 is connected to the unwinding chamber 64 such that the inside of the unwinding chamber 64 is maintained at a predetermined pressure (degree of vacuum) by exhausting the unwinding chamber 64 to reduce the pressure through the exhaust pipe 74a. In addition, in the exhaust pipe 74a, a pressure control valve 74b is provided to maintain the inside of the unwinding chamber 64 at a predetermined pressure by adjusting the opening degree to control the exhaust amount by the pump 74.

The pump 74 is not limited, and various well-known vacuum pumps (evacuation units) can be used. Regarding this point, the same also applies to a pump 132 provided in the exhaust line 130 of the film formation chamber 68 described below.

On the other hand, in the film formation chamber 68 that is separated from the unwinding chamber 64 by the partition wall 62, the film formation drum 70, a first film forming unit 100A, and a second film forming unit 100B are disposed.

The first film forming unit 100A and the second film forming unit 100B form the inorganic layer 16 on the support 12a by the dual-frequency capacitively coupled plasma CVD (CCP-CVD). In the example shown in the drawing, the first film forming unit 100A and the second film forming unit 100B include a shower electrode 114 that is a film formation electrode, a high frequency power supply 116, and a gas supply unit 118.

As described above, the film formation drum 70 is wound around the support 12a and transported. While transporting the support 12a wound around the film formation drum 70 in the longitudinal direction, the inorganic layer 16 is formed on the support 12a by the first film forming unit 100A and/or the second film forming unit 100B.

Here, the film formation drum 70 forms an electrode pair with the shower electrode 114 that is a film formation electrode (main electrode). Accordingly, in the film formation chamber 68 where the inorganic layer 16 is formed by the dual-frequency capacitively coupled plasma CVD, a bias power supply 76 for supplying bias power to the film formation drum 70 is connected.

In the inorganic film forming device 60 of the example shown in the drawing, a part of the film formation drum 70 protrudes from the partition wall 62 to the unwinding chamber 64, and forms a part of a partition wall for separating the unwinding chamber 64 and the film formation chamber 68 together with the partition wall 62. Accordingly, a gap between the film formation drum 70 and the partition wall 62 is a communication hole of the support 12b on which the support 12a and the inorganic layer 16 are formed that is wound around the film formation drum 70 and transported.

The inorganic film forming device that performs the manufacturing method according to the embodiment of the present invention is not limited to the configuration where the unwinding chamber and the film formation chamber are separated by the partition wall and the film formation drum. That is, the inorganic film forming device that performs the manufacturing method according to the embodiment of the present invention may have a configuration where the entire film formation drum is positioned in the film formation chamber and the unwinding chamber and the film formation chamber are separated by only a partition wall having a communication hole of the support.

In the film formation chamber 68, a cover consisting of a conductor material that is grounded to cover the film formation drum 70 may be provided between the first film forming unit 100A and the second film forming unit 100B, that is, corresponding to a region other than the film forming region.

By providing the cover, an unnecessary raw material gas flow can be suppressed, a plasma can be prevented from being generated in a redundant region, and the formation of the inorganic layer 16 can be stabilized.

In the first film forming unit 100A and the second film forming unit 100B, the shower electrode 114 is a well-known shower electrode (shower plate) that has an opening for supplying the raw material gas to a facing surface facing the film formation drum 70 and is used for plasma CVD.

The high frequency power supply 116 supplies plasma excitation power to the shower electrode 114. The high frequency power supply 116 is a well-known high frequency power supply used for plasma CVD, and examples thereof include a high frequency power supply of 13.56 MHz.

The gas supply unit 118 supplies the raw material gas to the shower electrode 114, and is a well-known gas supply unit used for plasma CVD. As described above, in the manufacturing method according to the embodiment of the present invention, the inorganic layer 16 is formed using monosilane gas (SiH₄), ammonia gas (NH₃), and hydrogen gas (H₂) as the raw material gas.

Further, the bias power supply 76 for supplying bias power to the film formation drum 70 is also not limited. That is, the bias power supply 76 is a well-known power supply that is used as a bias power supply in the dual-frequency capacitively coupled plasma CVD of simultaneously supplying the powers of two frequencies for generating a plasma. Examples of the bias power supply 76 include power supply for supplying power having a frequency of about 0.1 to 1.0 MHz.

In a preferable aspect, a gas analyzer 152 is connected to the film formation chamber 68 to measure concentrations (gas partial pressures) of monosilane gas, ammonia gas, and hydrogen gas, and the like in the film formation chamber 68 through an intake control valve 150.

The gas analyzer 152 is not limited, and various well-known analyzers that can measure a concentration (gas partial pressure) of each of gas components in mixed gas can be used. For example, a quadrupole mass spectrometer (QMS) can be used.

Further, the exhaust line 130 including the pump 132 and a pressure control valve 134 is connected to the film formation chamber 68 such that a predetermined pressure (degree of vacuum) in the film formation chamber 68 is maintained by exhausting the film formation chamber 68 to reduce the pressure.

In the exhaust line 130, the pressure control valve 134, the pump 132, a first detoxifying device 136, and an automatic switching valve 138 are provided in order from the upstream (film formation chamber 68) side. Even in the exhaust line 130, the inside of the film formation chamber 68 is maintained at a predetermined pressure by adjusting the opening degree of the pressure control valve 134 to control the exhaust amount by the pump 132.

An inert gas supply unit 140 is connected between the pressure control valve 134 and the pump 132 through a valve 140a. In addition, a monosilane detector 142 is connected between the first detoxifying device 136 and the automatic switching valve 138.

The automatic switching valve 138 switches a flow channel of the exhaust gas exhausted from the film formation chamber 68 for forming the inorganic layer 16 to any one of two directions. Among the flow channels that are switched by the automatic switching valve 138, one flow channel is directly open to the atmosphere, and the remaining flow channel is open to the atmosphere through a second detoxifying device 146.

The exhaust line 130 will be described below in detail.

In the inorganic film forming device 60, in a case where the inorganic layer 16 is formed, a support roll 12aR obtained by winding the support 12a on which the underlying organic layer 14 is formed is charged into the rotating shaft 92. Next, the support 12a drawn from the support roll 12aR is inserted into a predetermined transport path that reaches the winding shaft 108 through the pass rollers 94a to 94c, the film formation drum 70, and the pass rollers 106a to 106c.

The charging of the support roll 12aR and the insertion of the support 12a are performed such that a surface on the support 12a side opposite to the underlying organic layer 14 abuts against the film formation drum 70.

Next, the pump 74 and the pump 132 are driven to reduce the pressures in the unwinding chamber 64 and the film formation chamber 68 to predetermined film formation pressures. The pressure control of the unwinding chamber 64 is performed by the exhaust amount control by the pressure control valve 74b. In addition, the pressure control of the film formation chamber 68 is performed by the exhaust amount control by the pressure control valve 134.

In a case where the pressures of the unwinding chamber 64 and the film formation chamber 68 reach the predetermined pressures, the transport of the support 12a starts. As a result, the support 12a that is drawn from the support roll 12aR and is inserted into the predetermined path is guided by the pass rollers 94a to 94c, is wound around the film formation drum 70, and is transported.

Next, in the first film forming unit 100A and/or the second film forming unit 100B, monosilane gas, ammonia gas, and the hydrogen gas as the raw material gas are supplied from the shower electrode 114.

After the flow rate of the raw material gas supplied is stable, plasma excitation power is supplied from the high frequency power supply 116 to the shower electrode 114, and bias power is supplied from the bias power supply 76 to the film formation drum 70 that is a counter electrode of the shower electrode 114.

As a result, the inorganic layer 16 is formed on the surface of the underlying organic layer 14 of the support 12a that is wound around the film formation drum 70 and transported by dual-frequency capacitively coupled plasma CVD where monosilane gas, ammonia gas, and hydrogen gas are used as the raw material gas.

In addition, in a preferable aspect, the temperature adjustment unit is built in the film formation drum 70. Optionally, the inorganic layer 16 is formed on the support 12a while cooling or heating the support 12a using the film formation drum 70.

In the manufacturing method according to the embodiment of the present invention, film forming conditions of the inorganic layer 16, that is, the supply amounts (flow rates) of monosilane gas, ammonia gas, and hydrogen gas as the raw material gas, the plasma excitation power, the frequency of the plasma excitation power, the film formation pressure, the bias power, the frequency of the bias power, the substrate temperature (film formation temperature), and the like are not limited.

That is, in the method of manufacturing a gas barrier film according to the embodiment of the present invention, as in various well-known film formations by plasma CVD, the film forming conditions of the inorganic layer 16 may be appropriately set depending on the thickness of the inorganic layer 16 to be formed, a desired film formation rate, a film forming device to be used, the kind and thickness of the support, and the like.

The support 12b where the inorganic layer 16 is formed on the underlying organic layer 14 is guided to the pass rollers 106a to 106c, is transported to the winding shaft 108, and is wound around the winding shaft 108 to obtain a support roll 12bR around which the support 12b where the underlying organic layer 14 and the inorganic layer 16 are formed is wound.

In the manufacturing method according to the embodiment of the present invention, optionally, a protective film may be laminated on the inorganic layer 16 in the pass roller 106a directly downstream of the film formation drum 70.

In the support 12b on which the protective film F is laminated in the pass roller 106a, the vacuum chamber 72 is open to the atmosphere such that cleaned dry air is introduced. Next, the support roll 12bR is taken out from the vacuum chamber 72 and is charged into the organic film forming device 40.

In a case where two or more sets of laminated structures of the underlying organic layer 14 and the inorganic layer 16 are formed, the same formation of the underlying organic layer 14 and the inorganic layer 16 may be repeated according to the number of the laminated structures to be formed.

Here, in the manufacturing method according to the embodiment of the present invention, the inorganic layer is formed on the surface of the support 12a through RtoR by dual-frequency capacitively coupled plasma CVD where monosilane gas, ammonia gas, and hydrogen gas are raw material gas (film forming gas).

In addition, in the manufacturing method according to the embodiment of the present invention, during the formation of the inorganic layer 16, the exhaust amount of exhaust gas exhausted from the film formation chamber 68 through the exhaust line 130 increases over time. In the example shown in the drawing, by increasing the opening degree of the pressure control valve 134 over time, the exhaust amount of the exhaust gas from the film formation chamber 68 by the exhaust line 130 increases during the formation of the inorganic layer 16.

In the method of manufacturing a gas barrier film according to the embodiment of the present invention, with the above-described configuration, even in a case where a film formation length, that is, a length of the support 12a on which the inorganic layer 16 is to be continuously formed exceeds, for example, 500 m, the film property of the inorganic layer 16 to be formed can be maintained to be fixed.

As also described in JP2013-203050A, during manufacturing of a gas barrier film, an inorganic layer is formed on a surface of a support by dual-frequency capacitively coupled plasma CVD through RtoR by using monosilane gas, ammonia gas, and hydrogen gas as raw material gas.

Here, according to an investigation by the present inventors, it was found that, during the formation of the inorganic layer, in a case where the film formation length exceeds 500 m, there is a problem in that the film density of the inorganic layer is improved such that a fragile inorganic layer is formed.

The present inventors conducted a thorough investigation on the reason for this. As a result, the following reason was found.

That is, in a case where the inorganic layer is continuously formed by dual-frequency capacitively coupled plasma CVD, a plasma is spread in a wide region in the vicinity of the film formation drum 70 to which an electric field is applied. As a result, the plasma is generated not only in the film forming region where the shower electrode 114 and the film formation drum 70 face each other but also in a gap between the film formation drum 70 and the partition wall 62 that is a passage of the support 12b to the unwinding chamber 64.

In a case where the plasma is also generated in the gap between the film formation drum 70 and the partition wall 62, the partition wall 62 expands due to heat of the plasma. In a case where the partition wall 62 expands, the gap between the film formation drum 70 and the partition wall 62 that is a communication hole of the support 12b from the film formation chamber 68 to the unwinding chamber 64 is narrowed.

In the inorganic film forming device where the unwinding chamber 64 and the film formation chamber 68 are separated by the partition wall 62, it is preferable that the raw material gas, the activated raw material gas (radical), and the plasma are prevented from flowing into the unwinding chamber 64 as much as possible. Therefore, the width of the communication hole where the unwinding chamber 64 and the film formation chamber 68 communicate with each other in the thickness direction of the support 12b, in the example shown in the drawing, the gap between the film formation drum 70 and the partition wall 62 is preferably 10 mm or less and more preferably 5 mm or less.

In the inorganic film forming device 60, the flow of the raw material gas supplied to the film formation chamber 68 is mainly a direction toward the exhaust line 130. However, even in a case where the communication hole of the support 12b, that is, the gap between the film formation drum 70 and the partition wall 62 is narrow, the raw material gas is present to some extent in a range from the film formation chamber 68 to the unwinding chamber 64.

Here, the narrowing of the gap between the film formation drum 70 and the partition wall 62 refers to the narrowing of the flow channel of the raw material gas or the like from the film formation chamber 68 toward the unwinding chamber 64.

By narrowing the flow channel of the raw material gas from the film formation chamber 68 toward the unwinding chamber 64, the flow rate of the raw material gas from the film formation chamber 68 toward the unwinding chamber 64 decreases. In this case, even in a case where the flow rate of the raw material gas from the film formation chamber 68 toward the unwinding chamber 64 decreases, gas having a low molecular weight such as hydrogen gas is easily movable, and it is difficult to decrease the flow rate. On the other hand, monosilane gas has a higher molecular weight than hydrogen gas, and thus the flow rate from the film formation chamber 68 toward the unwinding chamber 64 relatively decreases.

As a result, during the continuous film formation, even in a case where the supply amount of the raw material gas is fixed, the film formation length, that is, the concentration of monosilane gas in the film formation chamber 68 increases over time. Accordingly, the density of the formed inorganic layer 16 increases, and the fragile inorganic layer 16 is formed.

That is, during the continuous film formation, monosilane active species having an ability to be incorporated into the inorganic layer 16 increases over time. Therefore, the film density of the formed inorganic layer 16 increases, and the fragile inorganic layer 16 is formed.

On the other hand, in the method of manufacturing a gas barrier film according to the embodiment of the present invention, in a case where the inorganic layer 16 is formed by the dual-frequency capacitively coupled plasma CVD through RtoR using monosilane gas, ammonia gas, and hydrogen gas as the raw material gas, assuming that the supply amount of the raw material gas is fixed, the exhaust amount of the exhaust gas exhausted from the film formation chamber 68 increases over time after the start of the film formation such that the monosilane gas concentration in the film formation chamber 68 is maintained to be fixed.

That is, during the continuous formation of the inorganic layer, the exhaust amount of the exhaust gas from the film formation chamber 68 where the monosilane gas concentration gradually increases over time due to the continuous formation such that the monosilane gas concentration in the film formation chamber 68 is maintained to be fixed. In other words, by increasing the exhaust amount of the exhaust gas from the inside of the film formation chamber 68 over time, the amount of monosilane active species having an ability to be incorporated into the inorganic layer 16 is maintained to be fixed, and the amount of monosilane active species incorporated into the inorganic layer 16 is maintained to be fixed.

As a result, in the manufacturing method according to the embodiment of the present invention, even in a case where the inorganic layer 16 is continuously formed such that the film formation length exceeds 500 m, an increase in the density of the inorganic layer 16 can be suppressed, the film property of the inorganic layer 16 to be formed can be maintained to be fixed, and the inorganic layer 16 can be formed.

Further, as described above, in a case where the inorganic layer 16 is continuously formed, the amount of the raw material gas leaking from the film formation chamber 68 to the unwinding chamber 64 through the gap between the partition wall 62 and the film formation drum 70 decreases, and the pressure in the film formation chamber 68 increases. On the other hand, in the present invention, the exhaust amount of the exhaust gas from the film formation chamber 68 increases over time. Therefore, the pressure of the film formation chamber 68 can be maintained to be fixed.

In the manufacturing method according to the embodiment of the present invention, the degree to which the exhaust amount of the exhaust gas from the film formation chamber 68 increases over time during the continuous film formation, that is, the degree to which the opening degree of the pressure control valve 134 increases over time during the film formation in the example shown in the drawing is not limited.

For example, using an experiment, a simulation, experience obtained by actual film formation, and the like, the amount of increase in the exhaust amount where the monosilane gas concentration in the film formation chamber 68 can be maintained to be fixed may be appropriately set over time, that is, according to the progress of the continuous film formation. In this aspect, the gas analyzer 152 is not necessarily provided.

It is preferable that, as in the inorganic film forming device 60 shown in FIG. 1, the gas analyzer 152 that measures the concentration of the raw material gas in the film formation chamber 68 is provided to measure the concentration of monosilane gas in the film formation chamber 68 during the film formation, that is, to measure the concentration of monosilane gas in the film formation chamber 68 over time.

In addition, the exhaust amount of the exhaust gas from the film formation chamber 68, that is, the opening degree of the pressure control valve 134 increases based on the detection result of the monosilane gas concentration by the gas analyzer 152 during the continuous formation of the inorganic layer 16 such that the monosilane gas concentration is fixed.

The measurement of the concentration of monosilane gas in the film formation chamber 68 by the gas analyzer 152 may be continuously or intermittently performed.

The increase of the exhaust amount of the exhaust gas from the film formation chamber 68 over time may be continuous or stepwise.

In addition, the timing of the increase of the exhaust amount of the exhaust gas may be continuous or intermittent, or a continuous increase and an intermittent increase may be combined.

In a case where the monosilane gas concentration in the film formation chamber 68 is maintained to be fixed, the monosilane gas concentration does not need to be completely fixed, and there may be a small variation in the concentration.

It is preferable that, in a case where the concentration of monosilane gas in the film formation chamber 68 at the start of film formation is normalized to “1”, the exhaust amount of the exhaust gas from the film formation chamber 68 is increased over time such that the concentration of monosilane gas in the film formation chamber 68 during the film formation is maintained to be 0.9 to 1.1.

In the present invention, the start of the film formation refers to the time point 60 seconds after the start of the supply of plasma excitation power to the shower electrode 114 (main electrode).

In the method of manufacturing a gas barrier film according to the embodiment of the present invention, it is preferable to decrease the pressure of the unwinding chamber 64, that is, to increase the degree of vacuum of the unwinding chamber 64 over time during the film formation.

As described above, in the inorganic film forming device 60, during the continuous formation of the inorganic layer 16, even in a case where the gap between the film formation drum 70 and the partition wall 62 is narrowed due to heating, the outflow amount of gas from the film formation chamber 68 to the unwinding chamber 64 decreases over time.

On the other hand, by reducing the pressure of the unwinding chamber 64 over time during the film formation, a decrease in the outflow amount of gas from the film formation chamber 68 to the unwinding chamber 64 can be reduced. As a result, the stabilization and the like the film forming gas flow in the film formation chamber 68 can be facilitated, and the inorganic layer 16 can be more stably formed.

Examples of a pressure control method of the unwinding chamber 64 include a method of continuously exhausting the unwinding chamber 64 at a fixed exhaust amount from the start of the formation of the inorganic layer 16.

As described above, in a case where the inorganic layer 16 is continuously formed by the inorganic film forming device 60, the gap between the film formation drum 70 and the partition wall 62 is narrowed over time, and the outflow amount of gas from the film formation chamber 68 to the unwinding chamber 64 decreases. Therefore, by continuously exhausting the unwinding chamber 64 at a fixed exhaust amount during the formation of the inorganic layer 16, the pressure of the unwinding chamber 64 can be reduced over time. In addition, the outflow amount of gas from the film formation chamber 68 to the unwinding chamber 64 decreases. Therefore, by controlling the pressure of the unwinding chamber 64 to be fixed, the exhaust amount decreases over time. On the other hand, by continuously exhausting the unwinding chamber 64 at a fixed exhaust amount without performing the pressure control, the exhaust amount from the unwinding chamber 64 can be ensured. Examples of the exhaust amount control include a method of continuously exhausting the unwinding chamber 64 at an exhaust amount that is 100% the exhaust amount of the pump 74.

A decrease in the pressure of the unwinding chamber 64 over time may be a continuous decrease or a stepwise decrease.

In addition, the timing of the decrease in the pressure of the unwinding chamber 64 may be continuous or intermittent, or a continuous decrease and an intermittent decrease may be combined.

Further, in the method of manufacturing a gas barrier film according to the embodiment of the present invention, it is preferable that the plasma excitation power supplied to the shower electrode 114 decreases over time during the film formation.

As a result, an increase in active monosilane radical (SiH₃ or the like) present in the film formation chamber 68 caused by promoting the decomposition of monosilane gas during heating of the shower electrode 114 can be suppressed. That is, the decomposition level of the monosilane gas is maintained to be fixed by reducing the plasma excitation power supplied to the shower electrode 114 over time during the film formation.

As a result, even in a case where the continuous film formation is performed, a change in the film property of the inorganic layer 16 can be suitably suppressed by fixing the amount of monosilane radical incorporated into the inorganic layer 16.

A decrease in the plasma excitation power supplied to the shower electrode 114 over time during the film formation may be performed, for example, depending on a measurement result in a case where the concentration (partial pressure) of monosilane radical in the film formation chamber 68 is measured by the gas analyzer 152 during the continuous film formation.

That is, depending on the concentration measurement result of the monosilane radical by the gas analyzer 152, the plasma excitation power supplied to the shower electrode 114 may decrease over time such that the concentration of monosilane radical in the film formation chamber 68 is fixed.

The decrease in plasma excitation power over time may be a continuous decrease or a stepwise decrease.

In addition, the timing of the decrease in the plasma excitation power may be continuous or intermittent, or a continuous decrease and an intermittent decrease may be combined.

As described above, in the method of manufacturing a gas barrier film according to the embodiment of the present invention, the exhaust amount of the exhaust gas from the film formation chamber 68 increases over time during the continuous formation of the inorganic layer 16.

That is, in the manufacturing method according to the embodiment of the present invention, the exhaust amount of monosilane gas that is explosive gas increases over time during the continuous formation of the inorganic layer 16. In addition, in the manufacturing method according to the embodiment of the present invention, the concentration of monosilane gas in the exhaust gas also increases over time as compared to the concentration of monosilane gas supplied to the film formation chamber 68.

Therefore, in the manufacturing method according to the embodiment of the present invention, the detoxifying treatment of removing monosilane gas from the exhaust gas exhausted from the film formation chamber 68 and exhausting the exhaust gas to the atmosphere is performed.

As described above, in the exhaust line 130 for exhausting the exhaust gas from the film formation chamber 68, in addition to the pressure control valve 134 and the pump 132 for performing the exhaust, the first detoxifying device 136 and the automatic switching valve 138 are provided downstream of the pump 132.

In the inorganic film forming device 60 of the example shown in the drawing, the detoxifying treatment of the exhaust gas is performed in the first detoxifying device 136.

The detoxifying treatment of the exhaust gas in the first detoxifying device 136 is not limited, and various well-known methods can be used as long as they are treatments capable of removing monosilane gas and more preferably further ammonia gas from the exhaust gas to be emitted to the atmosphere.

Examples of the abatement treatment include a combustion abatement device that combusts exhaust gas. However, the combustion abatement device treats exhaust gas containing gas that does not need to be treated, and thus has disadvantageous effects in that, for example, the treatment energy increases, power supply is required for the treatment such that the operation is difficult during an emergency such as blackout, water is required for the treatment, and the waste liquid treatment is required.

As an abatement device that does not have the disadvantageous effects of the combustion abatement device, an adsorption type abatement device is used as a preferable aspect in the manufacturing method according to the embodiment of the present invention.

By using a porous material (adsorbing material) depending on gas to be used in the adsorption type abatement device, gas to be removed is adsorbed (trapped) on the porous material to detoxify the exhaust gas. In the adsorption type abatement device, for example, by filling an adsorption column with a material for adsorbing gas to be removed and allowing the exhaust gas to pass through the adsorption column, the exhaust gas is detoxified, that is, silane gas is removed from the exhaust gas.

In the adsorption type abatement device, by selecting the porous material, gas to be removed can be selectively removed from mixed gas containing a plurality of gas. In addition, in the adsorption type abatement device, power is not required for detoxifying the exhaust gas, and the exhaust gas can be detoxified during blackout. Further, the adsorption type abatement device can selectively remove gas to be removed from gas to be treated through a simple treatment by allowing the gas to be treated through the adsorption column.

In the present invention, in a preferable aspect, a porous material that selectively adsorbs monosilane gas and ammonia gas from monosilane gas, ammonia gas, and hydrogen gas as the raw material gas is used, and the first detoxifying device 136 where the adsorption column is filled with the porous material is used.

In the inorganic film forming device 60, by allowing the exhaust gas to pass through the first detoxifying device 136 (adsorption column), monosilane gas and ammonia gas are removed from the exhaust gas by adsorption to detoxify (abate) the exhaust gas.

In the exhaust line 130, monosilane gas and ammonia gas are removed by the first detoxifying device 136, and the detoxified exhaust gas typically passes through the automatic switching valve 138 and is emitted as it is to the atmosphere as the exhaust gas.

Here, here, in a case where the exhaust gas contains active monosilane radical, monosilane radical, the monosilane radical is attached to the surface of the porous material of the first detoxifying device 136 to cover the porous material.

Therefore, in a case where the exhaust gas contains monosilane radical, the porous material cannot exhibit the adsorption action within a short period of time, and the exhaust gas cannot be detoxified by the first detoxifying device 136.

On the other hand, in the method of manufacturing a gas barrier film according to the embodiment of the present invention, monosilane gas, ammonia gas, and hydrogen gas are used as the raw material gas.

That is, in the manufacturing method according to the embodiment of the present invention, hydrogen gas is present in the film formation chamber 68. Therefore, in the manufacturing method according to the embodiment of the present invention, even in a case where monosilane radical is present in a region other than the gap between the shower electrode 114 and the film formation drum 70 that is the film forming region, hydrogen gas is present in the film formation chamber 68. Therefore, monosilane radical can return to monosilane gas by being bonded to hydrogen.

Therefore, in the manufacturing method according to the embodiment of the present invention, the amount of monosilane radical in the exhaust gas can be reduced, and the detoxifying device 136 can be appropriately operated for a long period of time.

In consideration of the above-described point, in the manufacturing method according to the embodiment of the present invention, a ratio of a flow rate of hydrogen gas to a flow rate of monosilane gas supplied to the film formation chamber 68 is preferably 7 or more and more preferably 8 or more in terms of a flow rate ratio “hydrogen gas/monosilane gas”.

By adjusting the flow rates of monosilane gas and hydrogen gas supplied to the film formation chamber 68 such that the flow rate ratio of “hydrogen gas/monosilane gas” is 7 or more, the amount of monosilane radical can be more suitably reduced, and the lifetime of the detoxifying device 136 can be more suitably increased.

In a case where the flow rate of hydrogen gas is excessively high with respect to that of monosilane gas or the like, a decrease in film formation rate or the like may occur. In consideration of this point, the flow rate ratio of “hydrogen gas/monosilane gas” supplied to the film formation chamber 68 is preferably 15 or less.

The hydrogen gas in the raw material gas also acts as carrier gas of the raw material gas, and further acts to adjust the film property of the inorganic layer 16.

In the exhaust line 130 of the inorganic film forming device 60 in the example shown in the drawing, in a preferable aspect, the inert gas supply unit 140 is connected between the pressure control valve 134 and the pump 132 through the valve 140a.

As described above, monosilane gas and ammonia gas are removed by the detoxifying device 136 to detoxify the exhaust gas, but the exhaust gas contains hydrogen gas that is explosive gas. Therefore, in the manufacturing method according to the embodiment of the present invention, on the downstream side of the pressure control valve 134, inert gas is supplied to the exhaust gas by the inert gas supply unit 140 such that the concentration (partial pressure) of hydrogen gas in the exhaust gas is 4% or less, and the exhaust gas is emitted to the atmosphere.

As a result, the concentration of hydrogen gas in the exhaust gas is adjusted to be the explosion limit or less, and the explosion of the exhaust gas caused by hydrogen gas can be prevented.

As the inert gas supply unit 140, various well-known gas supply units can be used.

In addition, as the inert gas, various kinds of well-known inert gas such as nitrogen gas or argon gas can be used.

The supply of the inert gas to the exhaust gas may performed at any timing as long as the timing is before emitting the exhaust gas to the atmosphere and downstream of the pressure control valve 134.

In the exhaust line 130 of the inorganic film forming device 60 in the example shown in the drawing, in a preferable aspect, the monosilane detector 142 is provided downstream of the first detoxifying device 136.

In addition, in a preferable aspect, the automatic switching valve 138 that switches the flow channel of the exhaust gas between two directions is provided downstream of the monosilane detector 142. One flow channel to which the flow channel of the exhaust gas is switched by the automatic switching valve 138 is a flow channel through which the exhaust gas is emitted to the atmosphere as it is. In the other flow channel to which the flow channel of the exhaust gas is switched by the automatic switching valve 138, in a preferable aspect, the second detoxifying device 146 is provided, and the exhaust gas passed through the second detoxifying device 146 is emitted to the atmosphere.

In the method of manufacturing a gas barrier film according to the embodiment of the present invention using the exhaust line 130, in a preferable aspect, monosilane in the exhaust gas that is detoxified by the first detoxifying device 136 is detected using the monosilane detector 142.

In addition, in a case where the monosilane detector 142 detects monosilane, the supply of the raw material gas and the supply of the plasma excitation power to the film formation chamber 68 are stopped to stop the formation of the inorganic layer 16. Further, by stopping the pump 132 to close the pressure control valve 134, the exhaust of the exhaust gas is stopped.

As a result, even in a case where monosilane gas is mixed in the exhaust gas due to the lifetime or the like of the porous material in the first detoxifying device 136, the monosilane gas can be prevented from being emitted to the atmosphere.

In addition, in the exhaust line 130, in a case where the monosilane detector 142 detects that the exhaust gas contains monosilane gas, as described above, the formation of the inorganic layer 16 and the exhaust are stopped, and the flow channel of the exhaust gas is switched from the steady emission side of the exhaust to the second detoxifying device 146 side by the automatic switching valve 138.

Next, the inert gas is supplied from the inert gas supply unit 140 to the exhaust line 130, the remaining exhaust gas in the exhaust line is swept away through the flow channel passing through the second detoxifying device 146, and the exhaust gas is detoxified by the second detoxifying device 146 to be emitted to the atmosphere.

In the method of manufacturing a gas barrier film according to the embodiment of the present invention, with the above-described configuration, even in a case where the exhaust gas contains monosilane gas due to deterioration or the like of the first detoxifying device 136, the exhaust gas containing monosilane gas can be safely treated.

As the monosilane detector 142, various well-known monosilane detection units can be used. Examples of the monosilane detector 142 include a gas sensor. As the gas sensor, various well-known gas sensors such as “a smart type gas detector GD-70D” manufactured by Riken Keiki Co., Ltd. can be used.

In addition, as the second detoxifying device 146, various well-known adsorption type abatement devices can be used, and an adsorption type abatement device is suitably used as in the above-described first detoxifying device 136.

In the method of manufacturing a gas barrier film according to the embodiment of the present invention, the concentration of monosilane in the exhaust gas monotonically increases over time during the formation of the inorganic layer 16. Accordingly, the concentration of monosilane radical in the exhaust gas may increase.

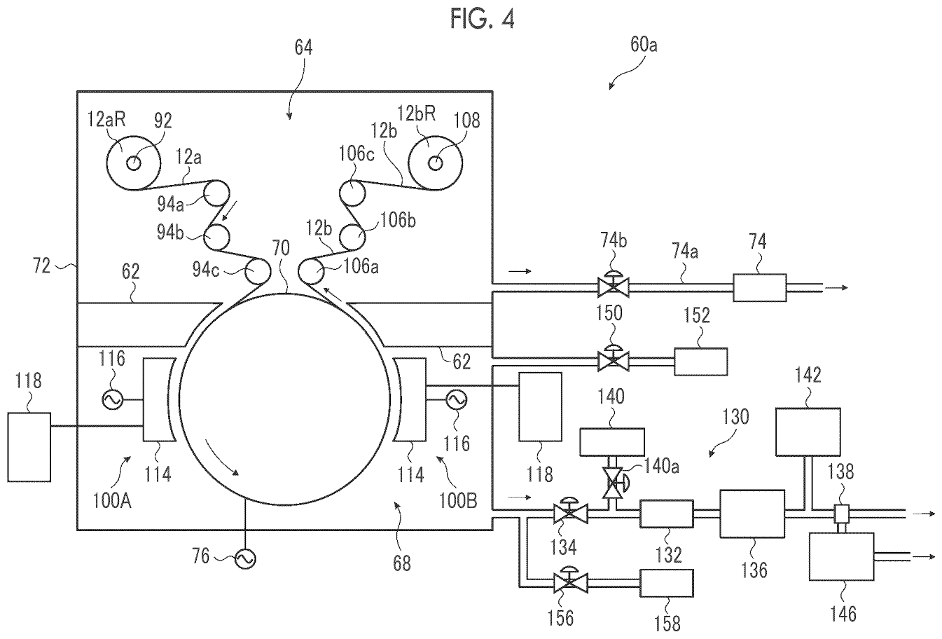

Accordingly, in the present invention, as in the inorganic film forming device 60a shown in FIG. 4, it is preferable that the exhaust line 130 is branched on the upstream side of the pressure control valve 134 and is connected to the same gas analyzer 158 as the above-described gas analyzer 152 through an intake control valve 156 to detect monosilane radical.

As a result, the progress of the reaction of returning monosilane radical to monosilane gas in a case where the raw material gas contains hydrogen gas can be checked. In addition, optionally, for example, by increasing the flow rate of hydrogen gas or controlling the exhaust amount of the exhaust gas based on the check result of the reaction progress, the inclusion of monosilane radical in the exhaust gas can be more suitably suppressed.

As described above, in the film formation chamber 68, the support 12b where the inorganic layer 16 is formed on the underlying organic layer 14 is guided to the pass rollers 106a to 106c, is transported to the winding shaft 108, and is wound around the winding shaft 108 to obtain a support roll 12bR around which the support 12b where the underlying organic layer 14 and the inorganic layer 16 are formed is wound.

The support roll 12bR around which the support 12b where the inorganic layer 16 is formed is wound is charged into the organic film forming device 40 again.

The support 12b is drawn from the support roll 12bR. Next, as in the above-described formation of the underlying organic layer 14, the composition for forming an organic layer that forms the protective organic layer 18 is applied by the application unit 42, is dried by the drying unit 46, and is irradiated with ultraviolet rays by the light irradiation unit 48 to polymerize and cure the organic compound for forming the protective organic layer 18. As a result, the gas barrier film 10 including the gas barrier film consisting of the underlying organic layer 14, the inorganic layer 16, and the protective organic layer 18 is prepared.

In the inorganic film forming device 60, in a case where a protective film is laminated on the surface of the inorganic layer 16, for example, the protective organic layer 18 is formed after peeling off the protective film in the transport roller pair 54 as described above.

Hereinbefore, the method of manufacturing a gas barrier film according to the embodiment of the present invention has been described in detail. However, the present invention is not limited to the above-described aspects and various improvements and changes may be made within a range not departing from the scope of the present invention.

### EXAMPLES

Hereinafter, the present invention will be described in detail using Examples. The present invention is not limited to specific examples described below.

### Example 1

### Support

A PET film (manufactured by Toyobo Co., Ltd., A4300, thickness: 100 μm, width: 1000 mm, length: 100 m) was prepared as the support, and an underlying organic layer and an inorganic layer were formed on a single surface side of the PET film in the following procedure.

### Formation of Underlying Organic Layer

TMPTA (manufactured by Daicel-Allnex Ltd.) and a photopolymerization initiator (ESACURE KTO 46, manufactured by Lamberti S.p.A.) were prepared and were weighed such that a weight ratio thereof was 95:5. These components were dissolved in methyl ethyl ketone. As a result, a coating liquid (composition for forming an organic layer) having a concentration of solid contents of 15% was obtained.

This coating liquid was applied to the surface of the support (PET film) through RtoR using a die coater, and the substrate was allowed to pass through a drying zone at 50° C. for 3 minutes. Next, while being heated using a backup roller at 80° C., the coating film was irradiated and cured with ultraviolet rays (cumulative irradiation amount: about 600 mJ/cm²), and the laminate was wound. Before contact with an initial film surface touch roller after the UV curing, a polyethylene protective film was bonded, and then the laminate was wound. The thickness of the underlying organic layer formed on the PET film was 2 μm.

### Formation of Inorganic Layer

By using the inorganic film forming device shown in FIG. 4, an inorganic layer was formed on the surface of the underlying organic layer.

Specifically, first, the wound support 12a with the underlying organic layer was fed, the protective film was peeled off in the final pass roller 94c before the film formation, and the inorganic layer was formed on the exposed underlying organic layer to manufacture a gas barrier film including the support, the underlying organic layer, and the inorganic layer.

The formation of the inorganic layer was performed using the second film forming unit 100B.

As raw material gas, monosilane gas (SiH₄, flow rate: 100 sccm), ammonia gas (NH₃, flow rate: 200 sccm), and hydrogen gas (H₂, flow rate: 1000 sccm) were used.

As the high frequency power supply 116 for supplying plasma excitation power to the shower electrode 114, a high frequency power supply having a frequency of 13.56 MHz was used. As the bias power supply 76 for supplying bias power to the film formation drum 70, a high frequency power supply having a frequency of 0.4 MHz was used.

Before contact with the initial pass roller 106a after the formation of the inorganic layer, a polyethylene protective film was bonded.

The plasma excitation power was 2 kW, and the bias power was 500 W.

In the RtoR, the transportation speed was 1 m/min, and the film formation pressure was 40 Pa.

As the first detoxifying device 136, an adsorption type abatement device where an adsorption column was filled with a porous material for selectively adsorbing monosilane gas and ammonia gas from monosilane gas, ammonia gas, and hydrogen gas as the raw material gas was used.

Specifically, as the first detoxifying device 136, “a dry abatement device VEGA-JGS” manufactured by Taiyo Nippon Sanso Corporation was used.

The film formation length of the inorganic layer was 1000 m. That is, the length of one support roll 12bR on which the inorganic layer was formed was 1000 m.

During the formation of the inorganic layer, each of the gas concentrations (partial pressures) in the film formation chamber 68 was measured by the gas analyzer 152 connected to the film formation chamber 68, and in a case where the concentration of monosilane gas in the film formation chamber at the start of film formation was normalized to 1, the opening degree of the pressure control valve 134 was increased over time such that the concentration of monosilane gas in the film formation chamber 68 during the film formation was 1. That is, the exhaust amount of the exhaust gas exhausted from the film formation chamber 68 was increased over time.

As a result, the opening degree of the pressure control valve 134 was 20% at the start of film formation, was gradually increased over time, and was 25% when the inorganic layer of 1000 m was formed.

During the film formation, monosilane gas in the exhaust gas was detected by the monosilane detector 142 provided downstream of the detoxifying device 136. In addition, during the film formation, the concentrations of monosilane gas (SiH₄) and monosilane radical (SiH₃) in the non-detoxified exhaust gas were measured by the gas analyzer 158 that was branched and provided upstream of the pressure control valve 134.

Further, regarding the film formation chamber 68, the concentration of monosilane radical was also measured by the gas analyzer 152.

The concentrations shown in Table 1 below are concentrations normalized to 1 at the start of film formation as in the monosilane gas concentration in the film formation chamber 68.

As the gas analyzer 152, the monosilane detector 142, and the gas analyzer 158, a quadrupole mass spectrometer (Qulee CGM, manufactured by ULVAC, Inc.) was used.

### Comparative Example 1

An inorganic layer of 1000 m was formed using the same method as that of Example 1, except that the opening degree of the pressure control valve 134 was fixed to 20%.

The monosilane gas concentration in the film formation chamber was increased from 1 to 1.4.

### Comparative Example 2

An inorganic layer was formed using the same method as that of Example 1, except that monosilane gas and ammonia gas were used as the raw material gas without using hydrogen gas.

However, when the inorganic layer of 50 m was formed, monosilane gas was not detected in the detoxified exhaust gas by the monosilane detector 142. Therefore, the film formation was stopped at 50 m.

### Example 2

An inorganic layer was formed using the same method as that of Example 1, except that the monosilane radical concentration in the film formation chamber 68 was measured by the gas analyzer 152, and the concentration of monosilane radical in the film formation chamber at the start of film formation was normalized to 1, and the plasma excitation power supplied to the shower electrode 114 was decreased over time such that the concentration of monosilane radical was 1 during the film formation.

The plasma excitation power supplied to the shower electrode 114 was 2 kW at the start of the film formation as in Example 1. During the film formation, the plasma excitation power was gradually decreased over time, and was 1.7 kW when the inorganic layer of 1000 m was formed.

### Example 3

An inorganic layer was formed using the same method as that of Example 1, except that the flow rate of hydrogen gas was changed from 1000 SCCM to 600 SCCM.

### Example 4

An inorganic layer was formed using the same method as that of Example 1, except that the flow rate of hydrogen gas was changed from 1000 SCCM to 800 SCCM.

### Flexibility of Inorganic Layer

A sample was obtained at a position of 999 m from the gas barrier film that was formed until 1000 m and was bent 100,000 times by a rod having a diameter of 10 mm.

Next, the water vapor transmission rate (WVTR) was measured using a calcium corrosion method (method described in JP2005-283561A). The measurement of the water vapor transmission rate was performed under conditions of a temperature of 25° C. and a relative humidity of 50%.

Regarding the water vapor transmission rate after bending the sample 100,000 times, a case where the value was 1×10⁻⁴ [g/m²/day] or less was evaluated as A, a case where the value was more than 1×10⁻⁴ [g/m²/day] and 1×10⁻³ [g/m²/day] or less was evaluated as B, and a case where the value was more than 1×10⁻³ [g/m²/day] was evaluated as C.

The table below also shows a film formation length until the evaluation of the flexibility test was C (film formation length until bending NG) in a case where the continuous film formation of more than 1000 m was performed.

### Lifetime of Detoxifying Device (Number of Rolls)

The number of rolls until the monosilane detector 142 of the exhaust line 130 detected monosilane by repeating the continuous film formation of 1000 m was counted.

Note that, in a case where the number of rolls was more than 50, the film formation was not performed any more.

### Comprehensive Evaluation

A case where the flexibility evaluation of the inorganic layer (water vapor transmission rate after the bending) was A and the number of rolls was 50 was evaluated as A, a case where the flexibility evaluation of the inorganic layer (water vapor transmission rate after the bending) was A and the number of rolls was less than 50 was evaluated as B, and the other cases were evaluated as C.

The above results are shown in the following table.

TABLE 1

| | | | | | | Exhaust | Concentration | | | |
|---|---|---|---|---|---|---|---|---|---|---|
| | | | | | | Valve | Film | | | |
| | Gas Flow Rate | | | | RF | Opening | Formation | | | |
| | SiH₄ | H₂ | NH₃ | | Power | Degree | Chamber | | Exhaust Line | |
| | [SCCM] | | | H₂/SiH₄ | [kW] | [%] | SiH₄ | SiH₃ | SiH₄ | SiH₃ |
| Comparative | 100 | 1000 | 200 | 10 | 2 | 20 | 1→1.4 | 1→1.8 | 1 | 1 |
| Example 1 | | | | | | | | | | |
| Example 1 | 100 | 1000 | 200 | 10 | 2 | 20→25 | 1 | 1→1.2 | 1→1.4 | 1 |
| Example 2 | 100 | 1000 | 200 | 10 | 2→1.7 | 20→27 | 1 | 1 | 1→1.6 | 1 |
| Comparative | 100 | 0 | 200 | 0 | 2 | 10→12 | 1 | 1→1.1 | 1→1.3 | 1→1.4 |
| Example 2 | | | | | | | | | | |
| Example 3 | 100 | 600 | 200 | 6 | 2 | 15→18 | 1 | 1→1.2 | 1→1.4 | 1→1.2 |
| Example 4 | 100 | 800 | 200 | 8 | 2 | 17→20 | 1 | 1→1.2 | 1→1.4 | 1 |

| | | | | Film | | |
|---|---|---|---|---|---|---|
| | | | | Formation | | |
| | Film | Detection | | Length | | |
| | Formation | of Exhausted | Inorganic | Until | Number | |
| | Length | SiH4 after | Layer | Bending | of | Comprehensive |
| | [m] | Detoxification | Flexibility | NG | Rolls | Evaluation |
| Comparative | 1000 | Not | C | 500 | 50 | C |
| Example 1 | | Detected | | | | |
| Example 1 | 1000 | Not | A | 1200 | 50 | A |
| | | Detected | | | | |
| Example 2 | 1000 | Not | A | 1600 | 50 | A |
| | | Detected | | | | |
| Comparative | 50 | Detected | — | — | 1 | C |
| Example 2 | | | | | | |
| Example 3 | 1000 | Not | A | 1200 | 20 | B |
| | | Detected | | | | |
| Example 4 | 1000 | Not | A | 1200 | 50 | A |
| | | Detected | | | | |

As shown in Table 1, in the manufacturing method according to the embodiment of the present invention where the exhaust amount of the exhaust gas from the film formation chamber increases over time during the formation of the inorganic layer, even in a case where an inorganic layer of 1000 m is formed, the appropriate inorganic layer having favorable flexibility can be formed.

In particular, as shown in Example 2, by decreasing the plasma excitation power over time during the film formation such that the concentration of monosilane radical in the film formation chamber was fixed, the appropriate inorganic layer having favorable flexibility can be formed until a longer film formation length.

In addition, as shown in Examples 3 and 4, by setting the flow rate ratio of hydrogen gas/monosilane gas to be 7 or more, the amount of monosilane radical in the exhaust gas can be reduced to increase the lifetime of the detoxifying device.

On the other hand, in Comparative Example 1 where the exhaust amount of the exhaust gas was fixed during the formation of the inorganic layer, the monosilane gas concentration and the monosilane radical concentration in the film formation chamber increased during the film formation. As a result, the flexibility of the inorganic layer was poor, and the appropriate inorganic layer was able to be formed only until 500 m.

In addition, in Comparative Example 2 where hydrogen gas was not used as the raw material gas, an increase in the monosilane radical concentration in the exhaust line was large, the surface of the porous material of the detoxifying device was covered with the monosilane radical when the inorganic layer was formed until 50 m, and monosilane gas was not able to be adsorbed on the porous material, and the monosilane gas was not detected such that the film formation needed to be stopped.

From the above results, the effects of the present invention are obvious.

The present invention is suitably applicable to manufacturing of a gas barrier film that is used for various applications.

### EXPLANATION OF REFERENCES

10: gas barrier film
12, 12a, 12b: support
12R, 12aR, 12bR: support roll
14: underlying organic layer
16: inorganic layer
18: protective organic layer
40: organic film forming device
42: application unit
46, 46a, 46b: drying unit
48: light irradiation unit
50, 92: rotating shaft
52, 108: winding shaft
60, 60a: inorganic film forming device
62: partition wall
64: unwinding chamber
68: film formation chamber
70: film formation drum
72: vacuum chamber
74, 132: pump
74a: exhaust pipe
74b: pressure control valve
94a to 94c, 106a to 106c pass roller
100A: first film forming unit
100B: second film forming unit
114: shower electrode
116: high frequency power supply
118: gas supply unit
130: exhaust line
134: pressure control valve
136: first detoxifying device
138: automatic switching valve
140: inert gas supply unit
140a: valve
142: monosilane detector
146: second detoxifying device
150, 156: intake control valve
152, 158: gas analyzer

What is claimed is:

1. A method of manufacturing a gas barrier film, the method comprising:
forming an inorganic layer on a surface of a support through roll-to-roll,
wherein the inorganic layer is formed using a film forming device including
a film formation chamber where the inorganic layer is formed on the support using a film formation drum for winding and transporting the support and a film formation electrode facing the film formation drum by dual-frequency capacitively coupled plasma CVD of supplying power to the film formation drum and the film formation electrode, and
an unwinding chamber where the support on which the inorganic layer is to be formed is fed from a support roll to the film formation chamber, the support on which the inorganic layer is formed in the film formation chamber is wound in a roll shape, and the film formation chamber is separated from the unwinding chamber by a partition wall having a passage portion of the support,
monosilane gas, ammonia gas, and hydrogen gas are supplied to the film formation chamber at a fixed flow rate to form the inorganic layer on the support in the film formation chamber, and an exhaust amount of exhaust gas exhausted from the film formation chamber is increased over time during the formation of the inorganic layer to maintain a concentration of monosilane gas in the film formation chamber to be fixed, and
a detoxifying treatment of detoxifying the exhaust gas is performed.

2. The method of manufacturing a gas barrier film according to claim 1,
wherein in a case where a concentration of monosilane gas in the film formation chamber at start of film formation is normalized to 1,
the exhaust amount of the exhaust gas from the film formation chamber is increased over time such that the concentration of monosilane gas in the film formation chamber is 0.9 to 1.1 during the formation of the inorganic layer.

3. The method of manufacturing a gas barrier film according to claim 1,
wherein a pressure of the unwinding chamber is decreased over time during the formation of the inorganic layer.

4. The method of manufacturing a gas barrier film according to claim 1,
wherein the power that is supplied to the film formation electrode is decreased over time during the formation of the inorganic layer.

5. The method of manufacturing a gas barrier film according to claim 1,
wherein in the detoxifying treatment of the exhaust gas, monosilane gas and ammonia gas are removed from the exhaust gas containing monosilane gas, ammonia gas, and hydrogen gas using a porous material.

6. The method of manufacturing a gas barrier film according to claim 1,
wherein a ratio of a flow rate of hydrogen gas to a flow rate of monosilane gas supplied to the film formation chamber is 7 or more in terms of a flow rate ratio “hydrogen gas/monosilane gas”.

7. The method of manufacturing a gas barrier film according to claim 1,
wherein inert gas is supplied to the exhaust gas at a position upstream or downstream of the detoxifying treatment such that a hydrogen gas concentration in the exhaust gas that is emitted to the atmosphere is 4% or less.

8. The method of manufacturing a gas barrier film according to claim 1,
wherein monosilane gas in the detoxified exhaust gas is detected by a detector, and in a case where the detector detects monosilane gas, the formation of the inorganic layer and the exhaust of the exhaust gas from the film formation chamber are stopped.

9. The method of manufacturing a gas barrier film according to claim 8,
wherein a normal exhaust flow channel, a second detoxifying treatment flow channel that detoxifies the exhaust gas, and a flow channel switching unit that switches a flow channel of the exhaust gas to the normal exhaust flow channel or the second detoxifying treatment flow channel are provided downstream of the detector,
in a state where the detector does not detect monosilane gas, the flow channel switching unit switches the flow channel of the exhaust gas to the normal exhaust flow channel, and
in a case where the detector detects monosilane gas, the flow channel switching unit switches the flow channel of the exhaust gas to the second detoxifying treatment flow channel such that inert gas is introduced from a position upstream of a position where the detoxifying treatment of the exhaust gas is performed, remaining exhaust gas is swept away to the second detoxifying treatment flow channel, and the exhaust gas is detoxified.

10. The method of manufacturing a gas barrier film according to claim 2,
wherein a pressure of the unwinding chamber is decreased over time during the formation of the inorganic layer.

11. The method of manufacturing a gas barrier film according to claim 2,
wherein the power that is supplied to the film formation electrode is decreased over time during the formation of the inorganic layer.

12. The method of manufacturing a gas barrier film according to claim 2,
wherein in the detoxifying treatment of the exhaust gas, monosilane gas and ammonia gas are removed from the exhaust gas containing monosilane gas, ammonia gas, and hydrogen gas using a porous material.

13. The method of manufacturing a gas barrier film according to claim 2,
wherein a ratio of a flow rate of hydrogen gas to a flow rate of monosilane gas supplied to the film formation chamber is 7 or more in terms of a flow rate ratio “hydrogen gas/monosilane gas”.

14. The method of manufacturing a gas barrier film according to claim 2,
wherein inert gas is supplied to the exhaust gas at a position upstream or downstream of the detoxifying treatment such that a hydrogen gas concentration in the exhaust gas that is emitted to the atmosphere is 4% or less.

15. The method of manufacturing a gas barrier film according to claim 2,
wherein monosilane gas in the detoxified exhaust gas is detected by a detector, and in a case where the detector detects monosilane gas, the formation of the inorganic layer and the exhaust of the exhaust gas from the film formation chamber are stopped.

16. The method of manufacturing a gas barrier film according to claim 15,
wherein a normal exhaust flow channel, a second detoxifying treatment flow channel that detoxifies the exhaust gas, and a flow channel switching unit that switches a flow channel of the exhaust gas to the normal exhaust flow channel or the second detoxifying treatment flow channel are provided downstream of the detector,
in a state where the detector does not detect monosilane gas, the flow channel switching unit switches the flow channel of the exhaust gas to the normal exhaust flow channel, and
in a case where the detector detects monosilane gas, the flow channel switching unit switches the flow channel of the exhaust gas to the second detoxifying treatment flow channel such that inert gas is introduced from a position upstream of a position where the detoxifying treatment of the exhaust gas is performed, remaining exhaust gas is swept away to the second detoxifying treatment flow channel, and the exhaust gas is detoxified.

17. The method of manufacturing a gas barrier film according to claim 3,
wherein the power that is supplied to the film formation electrode is decreased over time during the formation of the inorganic layer.

18. The method of manufacturing a gas barrier film according to claim 3,
wherein in the detoxifying treatment of the exhaust gas, monosilane gas and ammonia gas are removed from the exhaust gas containing monosilane gas, ammonia gas, and hydrogen gas using a porous material.

19. The method of manufacturing a gas barrier film according to claim 3,
wherein a ratio of a flow rate of hydrogen gas to a flow rate of monosilane gas supplied to the film formation chamber is 7 or more in terms of a flow rate ratio “hydrogen gas/monosilane gas”.

20. The method of manufacturing a gas barrier film according to claim 3,
wherein inert gas is supplied to the exhaust gas at a position upstream or downstream of the detoxifying treatment such that a hydrogen gas concentration in the exhaust gas that is emitted to the atmosphere is 4% or less.
